(19) United States
(12) Patent Application Publication
(10) Pub. No.: US 2009/0026618 A1
(43) Pub. Date: Jan. 29, 2009

(54) Semiconductor device including interlayer interconnecting structures and methods of forming the same

(75) Inventors: Hyun-Su Kim, Suwon-si (KR); Daeyong Kim, Yongin-si (KR); Eun-Ok Lee, Nam-gu (KR); Byunghee Kim, Seoul (KR); Jang-Hee Lee, Yongin-si (KR); Eun-Ji Jung, Suwon-si (KR); Gilheyun Choi, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/220,527

(22) Filed: Jul. 25, 2008

(30) Foreign Application Priority Data
Jul. 25, 2007 (KR) 10-2007-0074800
Mar. 7, 2008 (KR) 10-2008-0021625

(51) Int. Cl. H01L 21/768; H01L 23/48

(52) U.S. Cl. 257/751; 438/629; 257/E21.584; 257/E23.011

(57) ABSTRACT

In a method of forming a semiconductor device, and a semiconductor device formed according to the method, an insulating layer is provided on an underlying contact region of the semiconductor device. An opening is formed in the insulating layer to expose the underlying contact region. A seed layer is provided on sidewalls and a bottom of the opening, the seed layer comprising cobalt. A barrier layer of conductive material is provided in a lower portion of the opening, the seed layer being exposed on sidewalls of an upper portion of the opening. A metal layer is provided on the barrier layer in the opening to form an interlayer contact, the metal layer contacting the seed layer at the sidewalls of the upper portion of the opening.

### RELATED APPLICATIONS

This application claims priority under 35 U.S.C. 119 to Korean Patent Application No. 10-2007-0074800, filed on Jul. 25, 2007, and Korean Patent Application No. 10-2008-0021625, filed on Mar. 7, 2008, the content of which are incorporated herein by reference in its entirety.

### BACKGROUND OF THE INVENTION

With the continued emphasis on highly integrated electronic devices, there is an ongoing need for semiconductor devices that operate at higher speed and lower power and have increased device density. To achieve these goals, it is necessary for devices to be formed with increased integration and for device components to be formed of lower-resistivity materials. However, as the patterns used to form device components become smaller and as the space between adjacent patterns is decreased, there is a greater likelihood of signal interference for signals propagating over neighboring interconnect patterns and components.

Device performance is highly dependent on the capacitance of device components, and device capacitance is in turn dependent on the thickness of the conductive metal layers forming interconnects between components. For example, the thickness of bit lines running on an interlayer dielectric layer of a device has a direct impact on the capacitance of the device, since the capacitance depends in part on the area of capacitive interface between neighboring bit lines.

Device performance is further highly dependent on the resistivity of the materials used to form components and interconnect structures of the device. With further integration of devices, certain materials that are conventionally used for forming conductive interconnect patterns can become relatively unstable due to characteristics of the material that manifest themselves as the patterns become smaller.

With increased integration of devices, control over device capacitance and resistance properties is of primary concern, since these parameters are directly related to overall device performance and reliability.

### SUMMARY OF THE INVENTION

Embodiments of the present invention are directed to semiconductor devices and methods of forming the same wherein interlayer connecting structures provide low-resistivity connectivity with reduced capacitance in the resulting device. In particular, the embodiments of the present invention provide interlayer connecting structures that have a reduced pattern thickness on the interlayer dielectric layer for reducing the interface area of neighboring interconnect patterns. This is achieved while providing a lowered bulk metal resistance, as a seed layer comprising cobalt is used. At the same time, the presence of a relatively thick barrier layer in a lower portion of the interlayer connecting structure prevents chemical attack of the underlying silicide contact region during subsequent metal fill fabrication procedures. In addition, the presence of the barrier layer prevents diffusion of metal during the subsequent metal fill procedures into the underlying substrate or contact region, which diffusion can otherwise operate to increase contact resistance at the interface of the interlayer connecting structure and contact region.

In one aspect, a method of forming a semiconductor device comprises: providing an insulating layer on an underlying contact region of the semiconductor device; forming an opening in the insulating layer to expose the underlying contact region; providing a seed layer on sidewalls and a bottom of the opening, the seed layer comprising cobalt; providing a barrier layer of conductive material in a lower portion of the opening, the seed layer being exposed on sidewalls of an upper portion of the opening; and providing a metal layer on the barrier layer in the opening to form an interlayer contact, the metal layer contacting the seed layer at the sidewalls of the upper portion of the opening.

The underlying contact region can comprise at least one of a substrate, a doped region of a substrate, an epitaxial layer; a gate electrode of a transistor, a silicide region, and a conductive contact.

The seed layer can further be provided on the insulating layer and the metal layer can further be provided on the seed layer on the insulating layer and the method can further comprise: patterning the metal layer and the seed layer to form an interconnect structure on the insulating layer, the interconnect structure being in electrical contact with the underlying contact region by the interlayer contact.

The interconnect structure can comprise an interconnect line on the insulating layer.

The method can further comprise: planarizing the metal layer on the insulating layer to expose the insulating layer; providing a conductive layer on the metal layer; and patterning the conductive layer to form an interconnect structure on the insulating layer, the interconnect structure being in electrical contact with the underlying contact region by the interlayer contact.

The method can further comprise, prior to providing the conductive layer on the metal layer, providing one of a second barrier layer and second seed layer comprising cobalt on the exposed insulating layer; wherein patterning comprises patterning the conductive layer, and the one of the second barrier layer and second seed layer to form the interconnect structure.

The method can further comprise: planarizing the metal layer on the insulating layer to expose the insulating layer; providing a second insulating layer on the exposed insulating layer; patterning the second insulating layer to form an upper opening that exposes an upper portion of the metal layer; providing a conductive layer on the exposed portion of the metal layer; and planarizing the conductive layer to expose the second insulating layer to form an interconnect structure in the second insulating layer, the interconnect structure being in electrical contact with the underlying contact region by the interlayer contact.

The method can further comprise, prior to providing the conductive layer on the exposed portion of the metal layer, providing one of a second barrier layer and second seed layer comprising cobalt in the upper opening on the metal layer.

Providing the seed layer on the sidewalls and the bottom of the opening can comprise providing the seed layer using at least one of a chemical vapor deposition (CVD), physical vapor deposition (PVD) and atomic layer deposition (ALD) process.

Providing the barrier layer can comprise providing a barrier layer comprising at least one of TiN, TaN, RbN, VN, ZrN, HfN, MoN, ReN, WN, and TiZrN.

Providing a metal layer can comprise providing a metal layer comprising at least one of Al, Cu, and W.

Providing the barrier layer can comprise: providing the barrier layer on the insulating layer and in the opening to at least partially fill the opening; and partially removing the barrier layer in the opening so that the barrier layer remains in only the lower portion of the opening and so that the seed layer is exposed on sidewalls of the upper portion of the opening.

The method can further comprise, following providing the barrier layer in the lower portion of the opening, and prior to providing the metal layer, providing a second seed layer on the exposed sidewalls of the opening, the second seed layer comprising cobalt.

The device can be one of a non-volatile memory device, a volatile memory device, a DRAM volatile memory device, an SRAM volatile memory device, a NAND-type non-volatile memory device, a NOR-type non-volatile memory device, and a PRAM memory device.

The barrier layer can protect the underlying contact region when the metal layer is provided in the opening.

In another aspect, a semiconductor device comprises: an insulating layer on an underlying contact region of the semiconductor device; an opening in the insulating layer that exposes the underlying contact region; a seed layer on sidewalls and a bottom of the opening, the seed layer comprising cobalt; a barrier layer of conductive material in a lower portion of the opening; and a metal layer on the barrier layer in the opening, the metal layer contacting the seed layer at the sidewalls of the upper portion of the opening.

The underlying contact region can comprise at least one of a substrate, a doped region of a substrate, an epitaxial layer; a gate electrode of a transistor, a suicide region, and a conductive contact.

The seed layer can be further on the insulating layer and the metal layer can be further on the seed layer on the insulating layer and the metal layer and the seed layer can be patterned to form an interconnect structure on the insulating layer, the interconnect structure being in electrical contact with the underlying contact region.

The interconnect structure can comprise an interconnect line on the insulating layer.

The semiconductor device can further comprise a conductive layer on the insulating layer in contact with an upper portion of the metal layer at a top of the opening, wherein the conductive layer is patterned to form an interconnect structure on the insulating layer, the interconnect structure being in electrical contact with the underlying contact region.

The semiconductor device can further comprise one of a second barrier layer and second seed layer on the insulating layer in contact with the upper portion of the metal layer at the top of the opening; wherein the conductive layer is on the one of the second barrier layer and second seed layer.

The semiconductor device can further comprise: a second insulating layer on the insulating layer; an upper opening in the second insulating layer that exposes an upper portion of the metal layer; and a conductive layer in the upper opening in contact with the exposed upper portion of the metal layer at a top of the upper opening, wherein the conductive layer and the second barrier layer are patterned to form an interconnect structure in the insulating layer, the interconnect structure being in electrical contact with the underlying contact region.

The semiconductor device can further comprise one of a second barrier layer and second seed layer in the upper opening in contact with the exposed upper portion of the metal layer at the top of the upper opening, wherein the conductive layer is on the one of the second barrier layer and the second seed layer in the upper opening.

The seed layer can be on the sidewalls, and the bottom of the opening can be formed by at least one of a chemical vapor deposition (CVD), physical vapor deposition (PVD) and atomic layer deposition (ALD) process

The barrier layer can comprise at least one of TiN, TaN, RbN, VN, ZrN, HfN, MoN, ReN, WN, and TiZrN.

The metal layer can comprise at least one of Al, Cu, and W.

The semiconductor device can further comprise a second seed layer comprising cobalt at sidewalls of an upper portion of the opening, between the insulating layer and the metal layer.

The device can be one of a non-volatile memory device, a volatile memory device, a DRAM volatile memory device, an SRAM volatile memory device, a NAND-type non-volatile memory device, a NOR-type non-volatile memory device, and a PRAM memory device.

### BRIEF DESCRIPTION OF THE DRAWINGS

The foregoing and other objects, features and advantages of the embodiments of the invention will be apparent from the more particular description of preferred embodiments of the invention, as illustrated in the accompanying drawings in which like reference characters refer to the same parts throughout the different views. The drawings are not necessarily to scale, emphasis instead being placed upon illustrating the principles of the invention. In the drawings:

FIG. 1A is a planar top view of a semiconductor device including an interlayer interconnecting structure, in accordance with an embodiment of the present invention. FIG. 1B is a cross-sectional view of the embodiment of FIG. 1A, taken along section line A-A′, in accordance with an embodiment of the present invention.

FIG. 2A is a planar top view of a semiconductor device including an interlayer interconnecting structure, in accordance with another embodiment of the present invention. FIG. 2B is a cross-sectional view of the embodiment of FIG. 2A, taken along section line A-A′.

FIG. 3A is a planar top view of a semiconductor device including an interlayer interconnecting structure, in accordance with another embodiment of the present invention. FIG. 3B is a cross-sectional view of the embodiment of FIG. 3A, taken along section line A-A′.

FIGS. 4A-4E are cross-sectional views of a method of forming a semiconductor device, in accordance with an embodiment of the present invention.

FIG. 5A is a planar top view of a volatile memory semiconductor device including interlayer interconnecting structures, in accordance with an embodiment of the present invention. FIG. 5B is a cross-sectional view of the device of FIG. 5A, taken along section line C-C′.

FIG. 6A is a planar top view of a volatile memory semiconductor device including interlayer interconnecting structures, in accordance with another embodiment of the present invention. FIG. 6B is a cross-sectional view of the device of FIG. 6A, taken along section line C-C′.

FIG. 7A is a planar top view of a volatile memory semiconductor device including interlayer interconnecting structures, in accordance with another embodiment of the present invention. FIG. 7B is a cross-sectional view of the device of FIG. 7A, taken along section line C-C′.

FIG. 8 is a cross-sectional view of a semiconductor memory device including an interlayer interconnecting structure connected to a gate of a transistor device, in accordance with another embodiment of the present invention.

FIG. 9A is a planar top view of a non-volatile memory semiconductor device including interlayer interconnecting structures, in accordance with an embodiment of the present invention. FIG. 9B is a cross-sectional view of the device of FIG. 9A, taken along section line D-D′. FIG. 9C is a cross-sectional view of the device of FIG. 9A, illustrating interlayer interconnecting structures as applied to transistors in the core and peripheral regions of the device, in accordance with the present invention.

FIG. 10A is a planar top view of a non-volatile memory semiconductor device including interlayer interconnecting structures, in accordance with another embodiment of the present invention. FIG. 10B is a cross-sectional view of the device of FIG. 10A, taken along section line E-E′.

FIG. 11 is a block diagram of a memory system that includes memory devices that employ interlayer interconnecting structures in accordance with the embodiments of the present invention.

### DETAILED DESCRIPTION OF EMBODIMENTS

Embodiments of the present invention will now be described more fully hereinafter with reference to the accompanying drawings, in which preferred embodiments of the invention are shown. This invention may, however, be embodied in different forms and should not be construed as limited to the embodiments set forth herein. Like numbers refer to like elements throughout the specification.

It will be understood that, although the terms first, second, etc. are used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.). When an element is referred to herein as being “over” another element, it can be over or under the other element, and either directly coupled to the other element, or intervening elements may be present, or the elements may be spaced apart by a void or gap.

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

In a conventional interlayer contact used to provide connectivity between an underlying contact region of a semiconductor device, and an interconnect pattern on an upper layer, a contact hole is formed through an interlayer dielectric layer to expose the underlying contact region. A conformal seed layer is provided on the resulting structure, including the sidewalls and bottom of the contact hole, and a top surface of the interlayer dielectric layer. A conformal barrier layer is provided on the seed layer on the sidewalls and bottom of the contact hole, and on the top surface of the interlayer dielectric layer. A bulk metal layer is provided on the resulting structure, filling the contact hole. The resulting metal stack above the interlayer dielectric layer including the bulk metal layer, barrier layer, and seed layer is then patterned to expose the top surface of the interlayer dielectric layer and to thereby separate neighboring metal stack patterns. In one example, the neighboring metal stack patterns comprise bit lines of a semiconductor device that contact source/drain regions of an underlying transistor.

As mentioned above, device performance is highly dependent on the capacitance of device components, and device capacitance is in turn dependent on the thickness of the conductive metal layers forming the interconnects between components. In the above example, the thickness of the resulting bit lines running on the interlayer dielectric layer has a direct impact on the capacitance of the device, since the capacitance depends in part on the area of interface between neighboring bit lines.

Also as mentioned above, device performance is further highly dependent on the resistivity of the materials used to form components and interconnect structures of the device. In conventional configurations, the underlying contact region of the above example included a titanium silicide (TiSiₓ) layer in an effort to decrease contact resistance. In this case, a Ti/TiN seed layer is employed and a tungsten (W) metal fill is used. Resistance of the resulting structure was sufficiently low for conventional applications. With further integration of devices, it was determined that titanium silicide was relatively unstable for use as a silicide layer for the underlying contact region, and cobalt silicide (CoSiₓ) became the preferred silicide material.

In a case where cobalt silicide CoSiₓ is used as the silicide material, a seed layer of cobalt is preferred, for reducing resistance of the contact. However, absent the Ti/TiN layer in this configuration, the underlying cobalt silicide CoSiₓ layer is subject to fluorine (WF₆) attack during the tungsten metal fill. For this reason, a conformal Ti/TiN barrier metal layer is applied to the cobalt seed layer prior to the metal fill, in order to protect the underlying cobalt silicide CoSiₓ layer from damage during the tungsten metal fill. However, application of the Ti/TiN barrier metal layer according to the above example increases the height of the resulting interconnection line, or bit line, of the patterned metal stack, which, as described above, can negatively impact the capacitance of the resulting device.

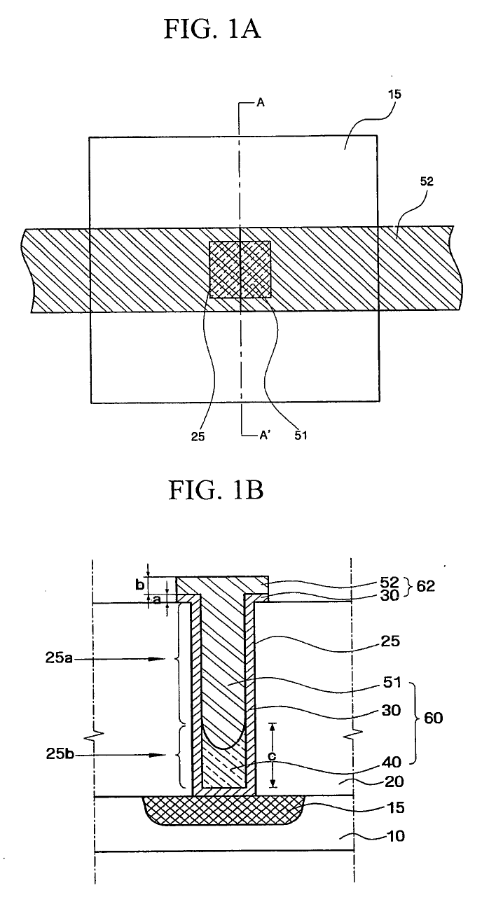

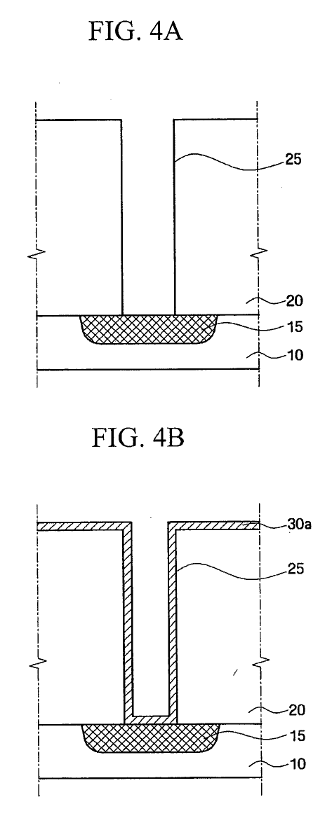

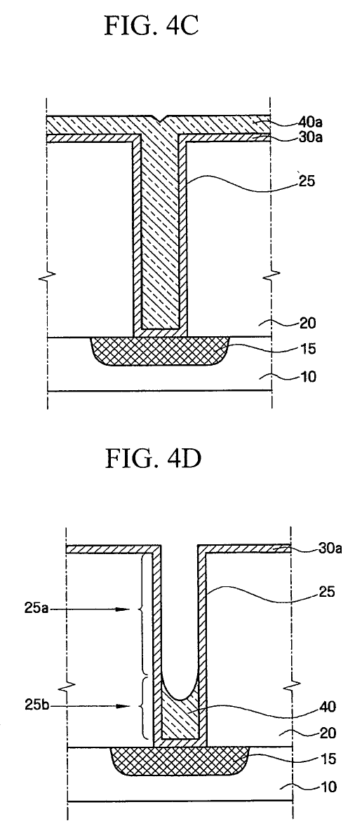

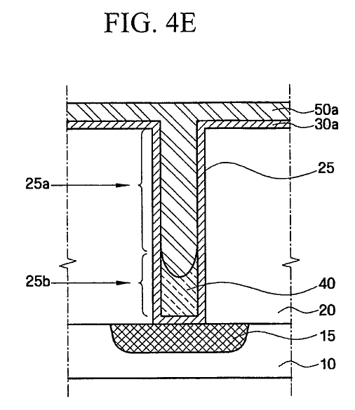

FIG. 1A is a planar top view of a semiconductor device including an interlayer interconnecting structure, in accordance with an embodiment of the present invention. FIG. 1B is a cross-sectional view of the embodiment of FIG. 1A, taken along section line A-A′, in accordance with an embodiment of the present invention. FIGS. 4A-4E are cross-sectional views of a method of forming a semiconductor device, in accordance with an embodiment of the present invention.

With reference to FIGS. 1A, 1B, and 4A, a region to be contacted 15, is provided in a semiconductor substrate 10. The region to be contacted 15 can take the form of any of a number of device components, and can include, for example, a terminal of a transistor, such as a gate, drain or source region of a transistor, which optionally has a silicide region on its upper surface. Other types of such regions to be contacted 15 by an interlayer interconnecting structure are equally applicable to the principles of the embodiments of the present invention, and can include for example, a doped region of a substrate and an epitaxial layer.

Referring to FIG. 4A, a first interlayer insulating layer 20 is formed on the underlying structure. The first interlayer insulating layer 20 is patterned according to conventional fabrication methods to form a first opening 25 in the first interlayer insulating layer 20 that exposes the underlying region to be contacted 15. It should be noted that any such openings and the resulting structures to be formed therein will not have perfectly vertical sidewalls, but instead will have tapered sidewalls as a natural result of the etching methods used to form the openings. In one example embodiment, the first interlayer insulating layer 20 comprises silicon oxide. In other embodiments, the first interlayer insulating layer 20 comprises at least one of flowable oxide (FOX), tonen silazene (TOSZ), updoped silicate glass (USG), boron silicate glass (BSG), phospho-silicate glass (PSG), boron phospho-silicate glass (BPSG), plasma-enhanced tetra-ethyl-ortho silicate (PE-TEOS), fluoride silicate glass (FSG), high density plasma (HDP), and other suitable insulating materials.

Referring to FIG. 4B, a seed layer 30a comprising cobalt is conformally applied to the resulting structure to cover a bottom and sidewalls of the opening 25. The seed layer 30a can be deposited using any of a number of applicable fabrication techniques, including chemical vapor deposition (CVD), physical vapor deposition (PVD), and atomic layer deposition (ALD), to a thickness for example in a range of about 5 Angstroms to about 100 Angstroms.

Referring to FIG. 4C, a barrier layer 40a is deposited to at least partially fill the opening 25 coated by the seed layer 30a. In this example, the barrier layer 40a fills the opening 25, and covers a top portion of the seed layer 30a on a top surface of the interlayer insulating layer 20. In various embodiments, the barrier layer comprises at least one of TiN, TaN, RbN, VN, ZrN, HfN, MoN, ReN, WN, and TiZrN, applied using standard deposition techniques, including CVD, PVD, and ALD. Although the embodiment illustrated in FIG. 4C depicts the barrier layer 40a completely filling the opening 25 coated by the seed layer 30a, the deposited barrier layer 40 can optionally partially fill the opening 25, for example a bottom portion of the opening 25, at this step.

Referring to FIG. 4D, a portion of the barrier layer 40a is removed in the opening, resulting in a recessed barrier layer 40 covering a bottom of the opening 25 and lower portions 25b of the sidewalls of the opening 25. At upper portions 25a of the sidewalls of the opening 25, the underlying seed layer 30a is exposed. In the embodiment of FIG. 4D, the top portion of the seed layer 30a on the upper surface of the interlayer insulating layer 20 is exposed during the barrier layer removal process; however, in other embodiments, a portion of the barrier layer 40a may remain on the top portion of the seed layer 30a on the upper surface of the interlayer insulating layer 20.

The barrier layer partial removal process depicted in FIG. 4D can be performed, in some embodiments, by a dry etch process or wet etch process. In one example, the etch process is timing-dependent with the timing parameters and etch concentration ensuring that an adequate amount of recessed barrier layer 40 remains in a lower portion of the opening 25. The remaining recessed barrier layer 40 operates to protect the underlying region to be contacted 15 from chemical damage during the subsequent contact fill process. For example, during the subsequent contact fill process, without the presence of the recessed barrier layer 40 in the bottom portion of the opening 25, the underlying region to be contacted 15 can become damaged by the material used to transport the contact fill material. For example, the underlying region can become damaged by chlorine Cl or fluorine Fl materials used to transport tungsten W material during a subsequent tungsten metal fill process. As a result, the conductive contact fill material can inadvertently be deposited at regions surrounding the point of contact between the interlayer contact and the underlying region to be contacted. Such inadvertent deposit of conductive material in these regions can contribute to shorting with neighboring contacts and regions, adversely affecting device reliability. The presence of the recessed barrier layer 40 during the subsequent deposit of the contact fill material mitigates or prevents this problem from occurring.

Referring to FIG. 4E, a conductive layer 50a is applied to the resulting structure, thereby filling the first opening 25 and making contact with the underlying region to be contacted 15 through the recessed barrier layer 40 and the bottom portion of the seed layer 30a that lies at the bottom of the opening 25. In one embodiment, the conductive layer 50a comprises a tungsten layer deposited using physical vapor deposition (PVD), chemical vapor deposition (CVD) or electroless plating, according to conventional fabrication methods. The conductive layer 50a can optionally be formed of a conductive material suitable for highly integrated fabrication methods, including metal having a low resistivity, such as W, Al or Cu. The presence of the recessed barrier layer 40 during the subsequent deposit of the conductive layer further mitigates or prevents the diffusion of metal during the subsequent metal fill procedures into the underlying region to be contacted 15 or into the substrate, which diffusion would otherwise increase contact resistance at the interface of the lower portion of the interlayer contact and the region to be contacted 15.

In an alternative embodiment, prior to application of the conductive layer 50a, a second cobalt seed layer can be conformally applied to the resulting structure. The original cobalt seed layer 30b (see FIG. 4B above) can become damaged during the etching process for partially removing the barrier layer 40 (see FIG. 4D above). A second application of the cobalt seed layer can be used to repair the so-damaged original cobalt seed layer 30b so that the resulting applied conductive layer 50b (see FIG. 4E above) will have the proper grain size.

Referring again to FIG. 1B, the conductive layer 50a and underlying seed layer 30a are then patterned according to conventional patterning techniques, resulting in formation of a conductive fill layer 51 portion in a top portion of the first opening 25, and a patterned interconnect layer 52 portion that lies on the interlayer insulating layer. A resulting interlayer contact 60 includes the conductive fill layer 51 portion and the seed layer 30 in the upper portion 25a of the opening 25, and the recessed barrier layer 40 and the seed layer 30 in the lower portion 25b of the opening 25. A resulting interconnect via 62 includes the patterned interconnect layer 52 and the patterned seed layer 30 that lie above the interlayer insulating layer 20.

The conductive fill layer 51 portion makes direct contact with the patterned seed layer 30 at the upper portion 25a of the opening. In a case, for example, where the patterned seed layer 30 comprises cobalt and the conductive layer 50a comprises tungsten, a relatively larger grain size in the resulting tungsten conductive fill layer 51 can be achieved, as compared to a case where, for example, a TiN seed layer is used for the tungsten deposit. As a result, lower resistivity can be achieved in the conductive fill layer 51.

At the same time, the presence of the recessed barrier layer 40 in the bottom portion 25b of the opening 25 ensures protection of the underlying region to be contacted 15 during deposit of the conductive layer 50a, thereby mitigating or preventing the potential for shorting problems, and resulting in reduced contact resistance at the interface by preventing metal diffusion, as described above.

In addition, the resulting height of the patterned interconnect via 62 that lies above the surface of the interlayer insulating layer 20 and can, for example, be configured to run in a horizontal direction relative to the substrate 10, includes the combined first thickness a of the patterned seed layer 30 and the second thickness b of the patterned interconnect layer 52. At the same time, a relatively thick recessed barrier layer 40 of a third thickness c remains in the bottom portion 25b of the opening 25. Thus, the patterned interconnect via 62 can be formed to have a reduced thickness, improving capacitance parameters of the resulting device, with the resulting thickness c of the recessed barrier layer 40 having a limited, or no, effect on the resulting thickness a+b of the patterned interconnect via 62. In some embodiments, the third thickness c of the recessed barrier layer 40 in the bottom portion 25b of the opening 25 can be greater than, or much greater than, the thickness a+b of the patterned interconnect via 62.

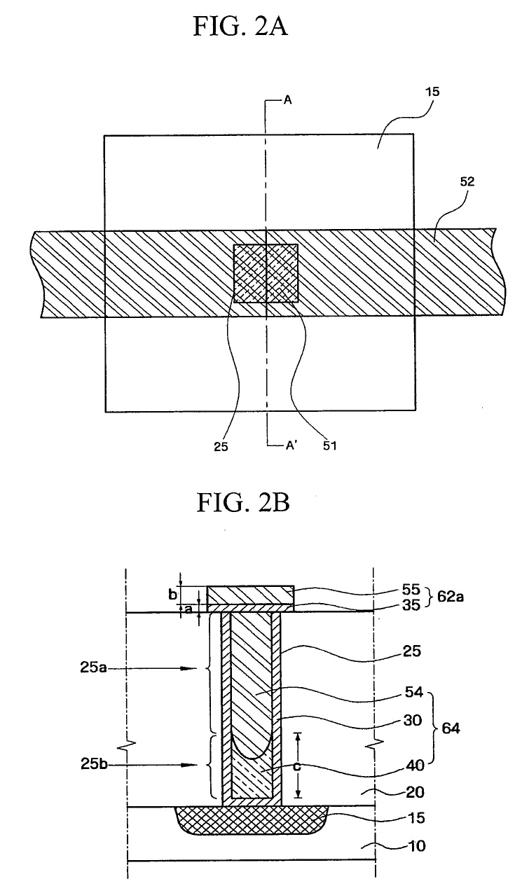

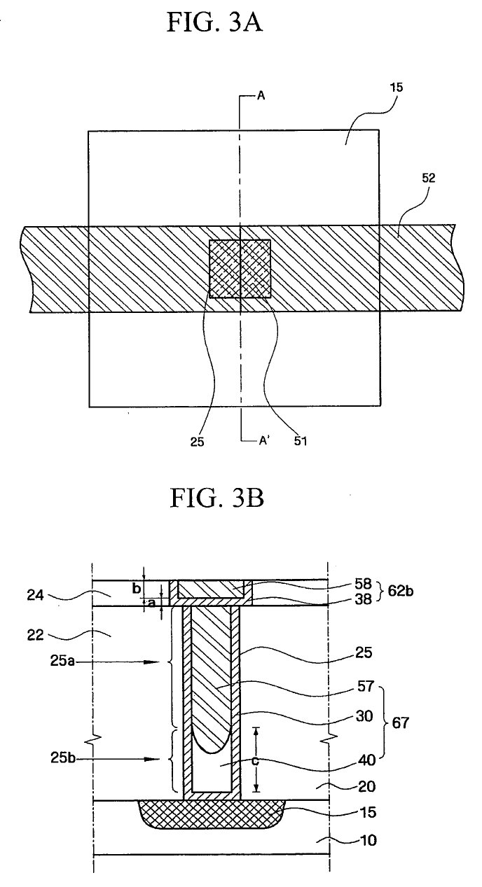

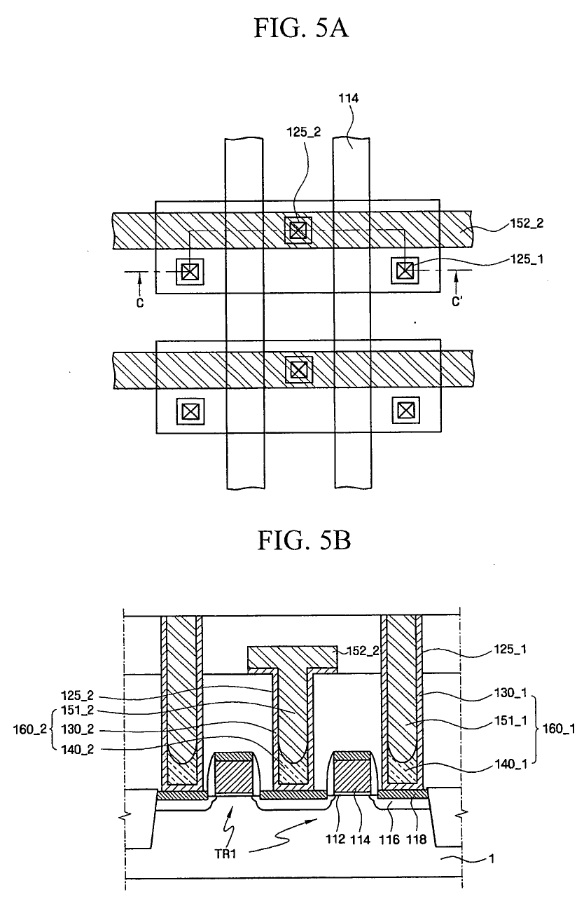

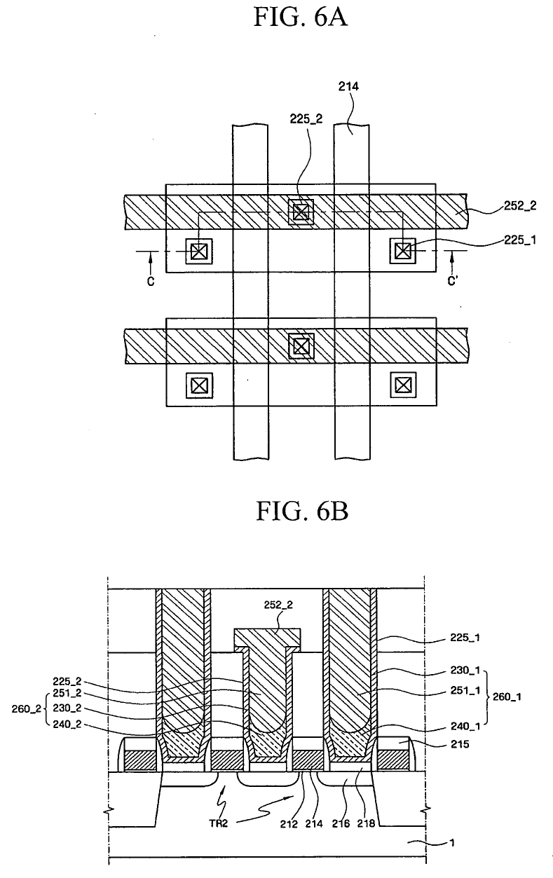

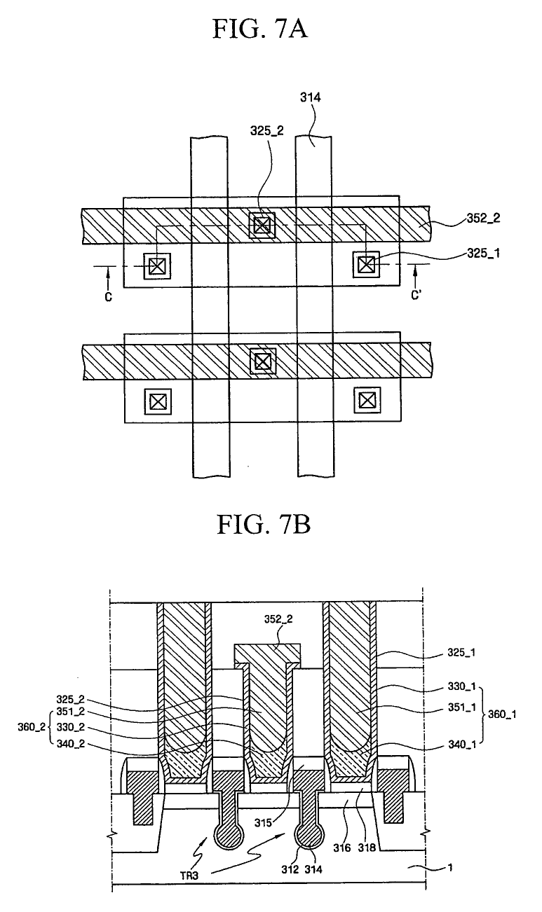

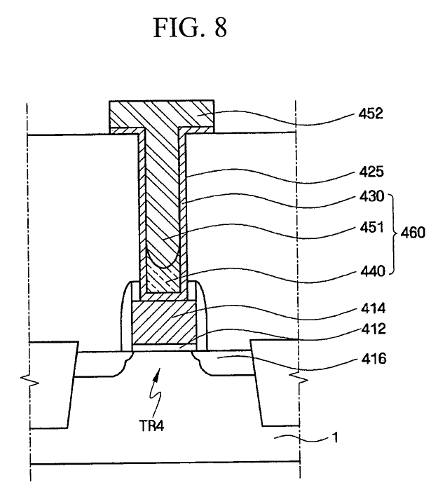

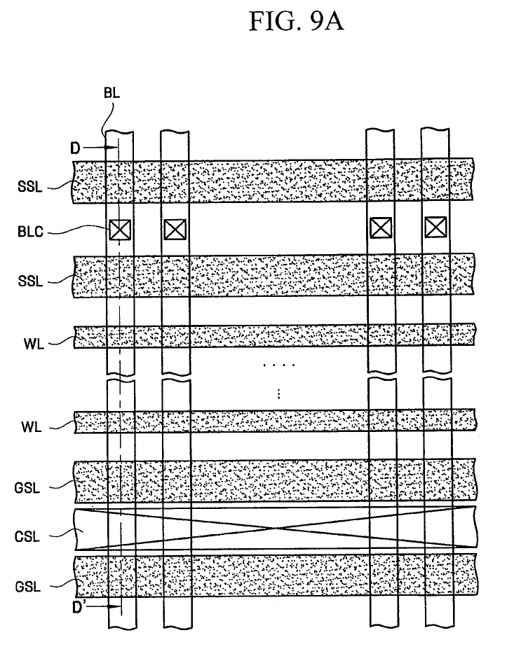

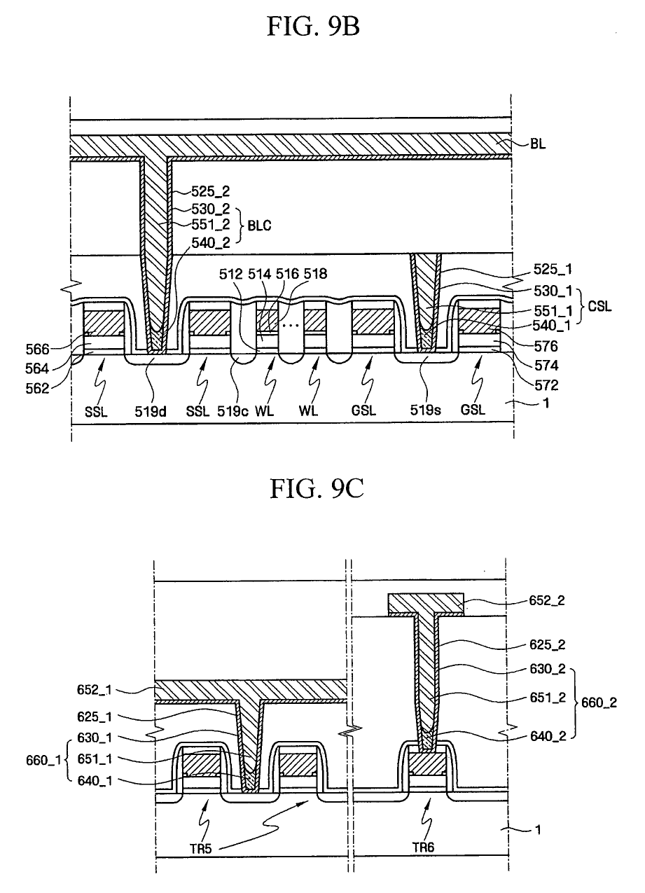

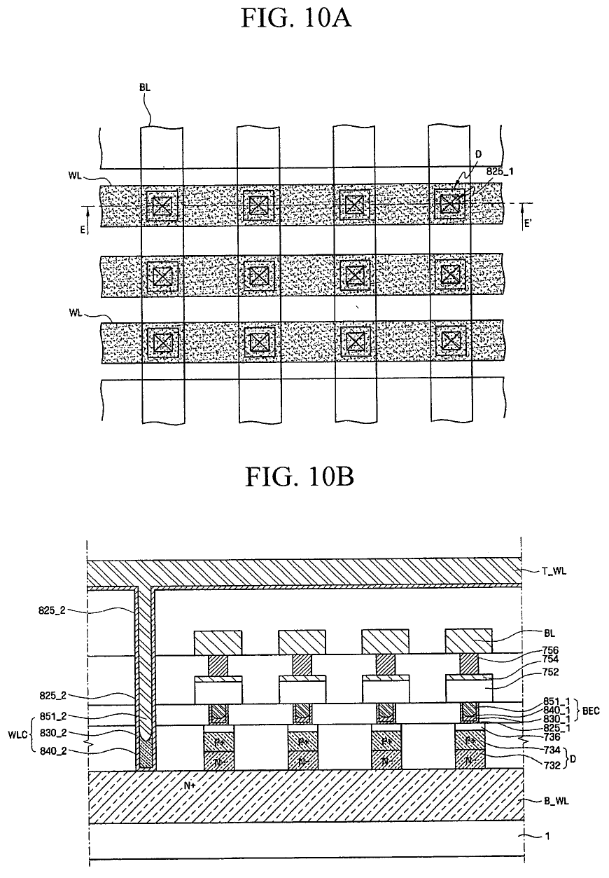

In this manner, in a case where the patterned interconnect via 62 forms a bit line of a semiconductor memory device, the bit line can be formed to have a reduced thickness, thereby improving capacitance parameters of the resulting device, while, at the same time, a barrier layer is present at the bottom of the opening to prevent shorting and to reduce contact resistance at the interface. This applies as well, for example, to the patterned interconnect vias 62a, 62b described below in connection with FIGS. 2A, 2B, 3A, 3B and to the bit lines 152_2 (FIGS. 5A and 5B), 252_2 (FIGS. 6A and 6B), 352_2 (FIGS. 7A and 7B), 452 (FIG. 8), bit line BL and common source line CSL (FIG. 9) and top word line T_WL (FIG. 10B), described below.

FIG. 2A is a planar top view of a semiconductor device including an interlayer interconnecting structure, in accordance with another embodiment of the present invention. FIG. 2B is a cross-sectional view of the embodiment of FIG. 2A, taken along section line A-A′. In this embodiment, following application of the conductive layer 50a used for filling the opening with a conductive material as shown in FIG. 4E, the resulting interconnect via 62a is formed using steps that are different from those described above in connection with FIGS. 1A and 1B. In particular, following deposit of the conductive layer 50a, the underlying interlayer contact 64, including the conductive fill layer portion 54 and the seed layer 30 in the upper portion 25a of the opening 25, and the recessed barrier layer 40 and the seed layer 30 in the lower portion 25b of the opening 25, is planarized to expose an upper surface of the interlayer insulating layer 20. Following this, a barrier layer 35 is applied to the upper surface of the resulting planarized structure, and a conductive interconnect layer 55 is applied on the barrier layer 35. The interconnect layer 55 and underlying barrier layer 35 are then patterned according to conventional patterning techniques, resulting in formation of an interconnect via 62a including the patterned interconnect layer 55 and patterned barrier layer 35 that lie above the interlayer insulating layer 20. The barrier layer 35 material can comprise any of a number of materials suitable for such purpose, including those barrier materials described above for use in connection with the recessed barrier layer 40. In an alternative embodiment, a seed layer can be used as a replacement for the barrier layer 35 of a material suitable for such purposes.

In this embodiment, the conductive fill layer 54 portion makes direct contact with the patterned seed layer 30 at the upper portion 25a of the opening. As a result, lower resistivity can be achieved in the conductive fill layer 54, as described above.

At the same time, the presence of the recessed barrier layer 40 in the bottom portion 25b of the opening 25 ensures protection of the underlying region to be contacted 15 during deposit of the conductive layer 50a, thereby mitigating or preventing the potential for shorting problems, and resulting in reduced contact resistance at the interface by preventing metal diffusion, as described above.

In addition, the resulting height of the patterned interconnect via 62a that runs in a horizontal direction relative to the substrate 10, includes the combined first thickness a of the patterned barrier layer 35 and the second thickness b of the patterned interconnect layer 55. At the same time, a relatively thick recessed barrier layer 40 of a third thickness c remains in the bottom portion 25b of the opening 25. Thus, the patterned interconnect via 62a can be formed to have a reduced thickness, improving capacitance parameters of the resulting device, as described above.

FIG. 3A is a planar top view of a semiconductor device including an interlayer interconnecting structure, in accordance with another embodiment of the present invention. FIG. 3B is a cross-sectional view of the embodiment of FIG. 3A, taken along section line A-A′. In this embodiment, following application of the conductive layer 50a used for filling the opening with a conductive material as shown in FIG. 4E, the resulting interconnect via 62b is formed using steps that are different from those described above in connection with FIGS. 1A and 1B, and 2A and 2B. In particular, following deposit of the conductive layer 50a, the underlying interlayer contact 67, including the conductive fill layer portion 57 and the seed layer 30 in the upper portion 25a of the opening 25, and the recessed barrier layer 40 and the seed layer 30 in the lower portion 25b of the opening 25, is planarized to expose an upper surface of the interlayer insulating layer 22. Following this, an upper interlayer insulating layer 24 is applied to the top surface of the resulting planarized structure, and an upper opening is formed in the layer 24 to expose a top of the interlayer contact 67. A barrier layer 38 is then applied to the upper surface of the resulting structure, and a conductive interconnect layer 58 is applied on the barrier layer 38. The interconnect layer 58 and underlying barrier layer 38 are then planarized according to conventional planarization techniques, resulting in formation of an interconnect via 62b including the patterned interconnect layer 58 and patterned barrier layer 38 that lie above the interlayer insulating layer 22. The barrier layer 38 material can comprise any of a number of materials suitable for such purpose, including those barrier materials described above for use in connection with the recessed barrier layer 40. In an alternative embodiment, a seed layer can be used as a replacement for the barrier layer 38 of a material suitable for such purposes.

In this embodiment, the conductive fill layer 57 portion makes direct contact with the patterned seed layer 30 at the upper portion 25a of the opening. As a result, lower resistivity can be achieved in the conductive fill layer 57, as described above.

At the same time, the presence of the recessed barrier layer 40 in the bottom portion 25b of the opening 25 ensures protection of the underlying region to be contacted 15 during deposit of the conductive layer 50a, thereby mitigating or preventing the potential for shorting problems, and resulting in reduced contact resistance at the interface by preventing metal diffusion, as described above.

In addition, the resulting height of the patterned interconnect via 62b that runs in a horizontal direction relative to the substrate 10, includes the combined first thickness a of the patterned barrier layer 38 and the second thickness b of the patterned interconnect layer 58. At the same time, a relatively thick recessed barrier layer 40 of a third thickness c remains in the bottom portion 25b of the opening 25. Thus, the patterned interconnect via 62b can be formed to have a reduced thickness, improving capacitance parameters of the resulting device, as described above.

FIG. 5A is a planar top view of a volatile memory semiconductor device including interlayer interconnecting structures, in accordance with an embodiment of the present invention. FIG. 5B is a cross-sectional view of the device of FIG. 5A, taken along section line C-C′.

In the embodiment of FIGS. 5A and 5B, a volatile memory semiconductor device in the form of a DRAM structure includes bit line patterns 152_2 that extend in a first direction on a semiconductor substrate 1 or silicon-on-insulator substrate 1. A common source transistor pair TR1 is formed on the substrate 1. Gate patterns 114 are formed on the substrate, insulated therefrom by a gate insulating layer 112. Source/drain regions 116 are formed in the substrate 1 at side portions of the gate patterns 114, and silicide layers 118 are formed on the source/drain regions 116. Interlayer contacts 160_1, 160_2 pass through an insulating layer to contact the source/drain regions 116. Each interlayer contact 160_1, 160_2 is formed in an opening 125_1, 125_2, and includes a patterned seed layer 130_1, 130_2, a recessed barrier layer 140_1, 140_2, and a conductive fill layer 151_1, 151_2, as described above. The first interlayer contacts 160_1 are connected to silicide layers 118 of the drain regions 116, and can be connected, for example, at top portions thereof, to storage contacts of the device. The second interlayer contact 160_2 is connected to metal line patterns 152_2, for example, bit lines, of the device.

FIG. 6A is a planar top view of a volatile memory semiconductor device including interlayer interconnecting structures, in accordance with another embodiment of the present invention. FIG. 6B is a cross-sectional view of the device of FIG. 6A, taken along section line C-C′.

In the embodiment of FIGS. 6A and 6B, a volatile memory semiconductor device in the form of a DRAM structure includes bit line patterns 252_2 that extend in a first direction on a semiconductor substrate 1 or silicon-on-insulator substrate 1. A common source transistor pair TR2 is formed on the substrate 1. Gate patterns 214 are formed on the substrate, insulated therefrom by a gate insulating layer 212. In this embodiment, epitaxial semiconductor layers 218 are formed on the substrate 1 at sidewalls of the gate patterns 214. Source/drain regions 216 are formed in the epitaxial layers 218 and in the substrate 1 at side portions of the gate patterns 214, and silicide layers (not shown) can optionally be formed on the epitaxial layers 218. In this embodiment, the source/drain regions are referred to as “elevated source/drain regions”, as they are elevated above the top surface of the substrate 1. Interlayer contacts 260_1, 260_2 pass through an insulating layer to contact the source/drain regions 216 at the epitaxial layers 218. Each interlayer contact 260_1, 260_2 is formed in an opening 225_1, 225_2, and includes a patterned seed layer 230_1, 230_2, a recessed barrier layer 240_1, 240_2, and a conductive fill layer 251_1, 251_2, as described above. The first interlayer contacts 260_1 are connected to the drain regions 216, and can be connected, for example, at top portions thereof, to storage contacts of the device. The second interlayer contact 260_2 is connected to metal line patterns 252_2, for example, bit lines, of the device.

FIG. 7A is a planar top view of a volatile memory semiconductor device including interlayer interconnecting structures, in accordance with another embodiment of the present invention. FIG. 7B is a cross-sectional view of the device of FIG. 7A, taken along section line C-C′.

In the embodiment of FIGS. 7A and 7B, a volatile memory semiconductor device in the form of a DRAM structure includes bit line patterns 352_2 that extend in a first direction on a semiconductor substrate 1 or silicon-on-insulator substrate 1. A common source transistor pair TR3 is formed on the substrate 1. Gate patterns 314 are formed on the substrate, insulated therefrom by a gate insulating layer 312. In this embodiment, the gate patterns 314 are formed in the configuration of a recessed channel transistor, which operates to extend the channel length of the resulting transistor by embedding the gate pattern 314 into the substrate 1 as shown. As in the configuration of FIGS. 6A and 6B above, in this embodiment, epitaxial semiconductor layers 318 are formed on the substrate at sidewalls of the gate patterns. Elevated source/drain regions 316 are formed in the epitaxial layers 318 and in the substrate 1 at side portions of the upper portions of the gate patterns 314, and silicide layers (not shown) can optionally be formed on the epitaxial layers 318. Interlayer contacts 360_1, 360_2 pass through an insulating layer to contact the source/drain regions 316 at the epitaxial layers 318. Each interlayer contact 360_1, 360_2 is formed in an opening 325_1, 325_2, and includes a patterned seed layer 330_1, 330_2, a recessed barrier layer 340_1, 340_2, and a conductive fill layer 351_1, 351_2, as described above. The first interlayer contacts 360_1 are connected to the drain regions 316, and can be connected, for example, at top portions thereof, to storage contacts of the device. The second interlayer contact 360_2 is connected to metal line patterns 352_2, for example, bit lines, of the device.

FIG. 8 is a cross-sectional view of a semiconductor memory device including an interlayer interconnecting structure connected to a gate of a transistor device, in accordance with another embodiment of the present invention. In the embodiment of FIG. 8, it is demonstrated that an interlayer interconnecting structure can be used to provide connectivity to a gate of a transistor. A transistor TR4 is formed on the substrate 1. Gate patterns 414 are formed on the substrate, insulated therefrom by a gate insulating layer 412. Source/drain regions 416 are formed in the substrate 1 at side portions of the gate patterns 414. An interlayer contact 460 passes through an insulating layer to contact a conductive portion of the gate pattern 414. The interlayer contact 460 is formed in an opening 425, and includes a patterned seed layer 430, a recessed barrier layer 440, and a conductive fill layer 451, as described above. The interlayer contact 460 can be connected, for example, at a top portion thereof, to a metal line pattern 452 of the device.

FIG. 9A is a planar top view of a non-volatile memory semiconductor device including interlayer interconnecting structures, in accordance with an embodiment of the present invention. FIG. 9B is a cross-sectional view of the device of FIG. 9A, taken along section line D-D′. FIG. 9C is a cross-sectional view of the device of FIG. 9A, illustrating interlayer interconnecting structures as applied to transistors in the core and peripheral regions of the device, in accordance with the present invention.

In the embodiment of FIGS. 9A-9C, a non-volatile memory semiconductor device in the form of a NAND-cell structure includes bit line patterns BL that extend in a first direction on a semiconductor substrate 1 or silicon-on-insulator substrate 1 and includes string selection lines SSL, word lines WL, ground selection lines GSL, and common source contacts CSC that extend in a second direction on the substrate 1. Transistor gate patterns 564, 566 for the string selection line SSL transistors and transistor gate patterns 574, 576 for the ground selection line GSL transistors are formed on the substrate, insulated therefrom by respective gate insulating layers 562, 572. Transistor gate patterns for the word selection line WL transistors are also formed on the substrate, and include a gate insulating layer 512, a charge storage layer 514, a blocking insulating layer 516, and a gate electrode 518. Source/drain regions 519c, 519d, 519s are formed in the substrate 1 at side portions of the gate patterns 564, 566, 518. Interlayer contacts in the form of a bit line contact BLC and a common source contact CSC pass through an insulating layer to contact the source/drain regions 519d, 519s. The common source contacts CSC are formed in an opening 525_1, and each includes a patterned seed layer 530_1, a recessed barrier layer 540_1, and a conductive fill layer 551_1, as described above. The bit line contacts BLC are formed in an opening 525_2, and each includes a patterned seed layer 530_2, a recessed barrier layer 540_2, and a conductive fill layer 551_2, as described above. The common source contacts CSC are connected at top portions thereof to the common source line CSL of the device. The bit line contacts BLC are connected at top portions thereof to the bit line BL of the device.

In the example of FIG. 9C, it is shown that the interlayer contacts in accordance with embodiments of the present invention find application in both the core and peripheral regions of a memory device. For example, a first interlayer contact 660_1 passes through an insulating layer to contact a source/drain region of a transistor TR5 in a core region of the device. The interlayer contact 660_1 is formed in an opening 625_1, and includes a patterned seed layer 630_1, a recessed barrier layer 640_1, and a conductive fill layer 651_1, as described above. The interlayer contact 660_1 can be connected, for example, at a top portion thereof, to a metal line pattern 652_1 of the core region of the device. At the same time, a second interlayer contact 660_2 passes through an insulating layer to contact a conductive portion of the gate pattern of a transistor TR6 in the peripheral region of the device. The interlayer contact 660_2 is formed in an opening 625_2, and includes a patterned seed layer 630_2, a recessed barrier layer 640_2, and a conductive fill layer 651_2, as described above. The interlayer contact 660_2 can be connected, for example, at a top portion thereof, to a metal line pattern 652_2 of the peripheral region of the device.

FIG. 10A is a planar top view of a non-volatile memory semiconductor device including interlayer interconnecting structures, in accordance with another embodiment of the present invention. FIG. 10B is a cross-sectional view of the device of FIG. 10A, taken along section line E-E′.

In the embodiment of FIGS. 10A and 10B, a non-volatile memory semiconductor device in the form of a diode-type phase-change RAM (PRAM) structure includes bit line patterns BL that extend in a first direction on a semiconductor substrate 1 or silicon-on-insulator substrate 1 and includes word lines WL that extend in a second direction on the substrate 1. Each transistor element includes a phase-change material pattern 752, a top electrode 754, and an electrode contact 756 that connects the electrode to a bit line BL of the device. Each transistor element further includes a diode D including an N− portion adjacent a P+ portion and a diode electrode 736. Each N− portion is connected to a bottom word line B_WL. Each phase-change material pattern 752 is connected to the diode electrode 736 via a corresponding bottom electrode contact BEC. The bottom electrode contact BEC in this example, takes the form of an interlayer contact of the type described herein, and is formed in a corresponding opening 825_1, and includes a patterned seed layer 830_1, a recessed barrier layer 840_1, and a conductive fill layer 851_1, as described above. Another interlayer contact in the form of a word line contact WLC connects a top word line T_WL to a bottom word line B_WL, is formed in a corresponding opening 825_2 and includes a patterned seed layer 830_2, a recessed barrier layer 840_2, and a conductive fill layer 851_2, as described above.

The embodiments of the present invention are equally applicable to other forms of memory, both volatile and non-volatile, and devices that include both volatile and non-volatile memory. For example, although applicability of the embodiments of the present invention to NAND-type and PRAM-type non-volatile memory devices is shown above, the embodiments are equally applicable to NOR-type non-volatile memory devices, resistive RAM (RRAM) memory devices, magnetic RAM (MRAM) memory devices, and SRAM memory devices, among others.

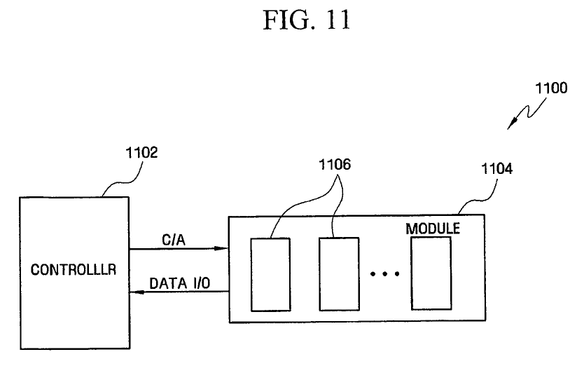

FIG. 11 is a block diagram of a memory system that includes memory devices that employ interlayer interconnecting structures in accordance with the embodiments of the present invention. The memory system 1100 includes a memory controller 1102 that generates command and address signals C/A and a memory module 1104 that includes a plurality of memory devices 1106. The memory module 1104 receives the command and address signals C/A from the memory controller, and, in response stores and retrieving data DATA I/O to and from at least one of the memory devices 1106. Each memory device includes a plurality of addressable memory cells and a decoder that receives the command and address signals, and that generates a row signal and a column signal for accessing at least one of the addressable memory cells during programming and read operations. Each of the components of the memory system 1100, including the controller 1102, the module electronics 1104, and the memory devices 1106 can employ the interlayer interconnecting structure configurations disclosed herein.

In the embodiments described herein, the interlayer interconnecting structures can take the form of both plug-type contacts and line-type contacts. For example, in a case wherein the interlayer interconnecting structures comprise line-type contacts, they can comprise bit lines of a semiconductor memory device that extend in a horizontal direction of the device. Therefore, the term “opening”, as used herein to describe the opening in which the interlayer interconnecting structure is formed, can refer to both a hole-type opening and a line-type opening, depending on the application. The same holds true for the resulting conductive fill layer that makes conductive contact though the opening.

While embodiments of the invention have been particularly shown and described with references to preferred embodiments thereof, it will be understood by those skilled in the art that various changes in form and details may be made herein without departing from the spirit and scope of the invention as defined by the appended claims.

What is claimed is:

1. A method of forming a semiconductor device comprising:
providing an insulating layer on an underlying contact region of the semiconductor device;
forming an opening in the insulating layer to expose the underlying contact region;
providing a seed layer on sidewalls and a bottom of the opening, the seed layer comprising cobalt;
providing a barrier layer of conductive material in a lower portion of the opening, the seed layer being exposed on sidewalls of an upper portion of the opening; and
providing a metal layer on the barrier layer in the opening to form an interlayer contact, the metal layer contacting the seed layer at the sidewalls of the upper portion of the opening.

2. The method of claim 1 wherein the underlying contact region comprises at least one of a substrate, a doped region of a substrate, an epitaxial layer; a gate electrode of a transistor, a silicide region, and a conductive contact.

3. The method of claim 1 wherein the seed layer is further provided on the insulating layer and wherein the metal layer is further provided on the seed layer on the insulating layer and further comprising:
patterning the metal layer and the seed layer to form an interconnect structure on the insulating layer, the interconnect structure being in electrical contact with the underlying contact region by the interlayer contact.

4. The method of claim 3 wherein the interconnect structure comprises an interconnect line on the insulating layer.

5. The method of claim 1 further comprising:
planarizing the metal layer on the insulating layer to expose the insulating layer;
providing a conductive layer on the metal layer; and
patterning the conductive layer to form an interconnect structure on the insulating layer, the interconnect structure being in electrical contact with the underlying contact region by the interlayer contact.

6. The method of claim 5 further comprising prior to providing the conductive layer on the metal layer, providing one of a second barrier layer and second seed layer comprising cobalt on the exposed insulating layer; and wherein patterning comprises patterning the conductive layer, and the one of the second barrier layer and second seed layer to form the interconnect structure.

7. The method of claim 1 further comprising:
planarizing the metal layer on the insulating layer to expose the insulating layer;
providing a second insulating layer on the exposed insulating layer;
patterning the second insulating layer to form an upper opening that exposes an upper portion of the metal layer;
providing a conductive layer on the exposed portion of the metal layer; and
planarizing the conductive layer to expose the second insulating layer to form an interconnect structure in the second insulating layer, the interconnect structure being in electrical contact with the underlying contact region by the interlayer contact.

8. The method of claim 7 further comprising prior to providing the conductive layer on the exposed portion of the metal layer, providing one of a second barrier layer and second seed layer comprising cobalt in the upper opening on the metal layer.

9. The method of claim 1 wherein providing the seed layer on the sidewalls and the bottom of the opening comprises providing the seed layer using at least one of a chemical vapor deposition (CVD), physical vapor deposition (PVD) and atomic layer deposition (ALD) process.

10. The method of claim 1 wherein providing the barrier layer comprises providing a barrier layer comprising at least one of TiN, TaN, RbN, VN, ZrN, HfN, MoN, ReN, WN, and TiZrN.

11. The method of claim 1 wherein providing a metal layer comprises providing a metal layer comprising at least one of Al, Cu, and W.

12. The method of claim 1 wherein providing the barrier layer comprises:
providing the barrier layer on the insulating layer and in the opening to at least partially fill the opening; and
partially removing the barrier layer in the opening so that the barrier layer remains in only the lower portion of the opening and so that the seed layer is exposed on sidewalls of the upper portion of the opening.

13. The method of claim 1 further comprising, following providing the barrier layer in the lower portion of the opening, and prior to providing the metal layer, providing a second seed layer on the exposed sidewalls of the opening, the second seed layer comprising cobalt.

14. The method of claim 1 wherein the device is one of a non-volatile memory device, a volatile memory device, a DRAM volatile memory device, an SRAM volatile memory device, a NAND-type non-volatile memory device, a NOR-type non-volatile memory device, and a PRAM memory device.

15. The method of claim 1 wherein the barrier layer protects the underlying contact region when the metal layer is provided in the opening.

16. A semiconductor device comprising:
an insulating layer on an underlying contact region of the semiconductor device;
an opening in the insulating layer that exposes the underlying contact region;
a seed layer on sidewalls and a bottom of the opening, the seed layer comprising cobalt;
a barrier layer of conductive material in a lower portion of the opening; and
a metal layer on the barrier layer in the opening, the metal layer contacting the seed layer at the sidewalls of the upper portion of the opening.

17. The semiconductor device of claim 16 wherein the underlying contact region comprises at least one of a substrate, a doped region of a substrate, an epitaxial layer; a gate electrode of a transistor, a silicide region, and a conductive contact.

18. The semiconductor device of claim 16 wherein the seed layer is further on the insulating layer and wherein the metal layer is further on the seed layer on the insulating layer and wherein the metal layer and the seed layer are patterned to form an interconnect structure on the insulating layer, the interconnect structure being in electrical contact with the underlying contact region.

19. The semiconductor device of claim 18 wherein the interconnect structure comprises an interconnect line on the insulating layer.

20. The semiconductor device of claim 16 further comprising a conductive layer on the insulating layer in contact with an upper portion of the metal layer at a top of the opening, wherein the conductive layer is patterned to form an interconnect structure on the insulating layer, the interconnect structure being in electrical contact with the underlying contact region.

21. The semiconductor device of claim 20 further comprising one of a second barrier layer and second seed layer on the insulating layer in contact with the upper portion of the metal layer at the top of the opening; and wherein the conductive layer is on the one of the second barrier layer and second seed layer.

22. The semiconductor device of claim 16 further comprising:
a second insulating layer on the insulating layer;
an upper opening in the second insulating layer that exposes an upper portion of the metal layer; and
a conductive layer in the upper opening in contact with the exposed upper portion of the metal layer at a top of the upper opening, wherein the conductive layer and the second barrier layer are patterned to form an interconnect structure in the insulating layer, the interconnect structure being in electrical contact with the underlying contact region.

23. The semiconductor device of claim 22 further comprising one of a second barrier layer and second seed layer in the upper opening in contact with the exposed upper portion of the metal layer at the top of the upper opening, and wherein the conductive layer is on the one of the second barrier layer and the second seed layer in the upper opening.

24. The semiconductor device of claim 16 wherein the seed layer on the sidewalls and the bottom of the opening is formed by at least one of a chemical vapor deposition (CVD), physical vapor deposition (PVD) and atomic layer deposition (ALD) process

25. The semiconductor device of claim 16 wherein the barrier layer comprises at least one of TiN, TaN, RbN, VN, ZrN, HfN, MoN, ReN, WN, and TiZrN.

26. The semiconductor device of claim 16 wherein the metal layer comprises at least one of Al, Cu, and W.

27. The semiconductor device of claim 16 further comprising a second seed layer comprising cobalt at sidewalls of an upper portion of the opening, between the insulating layer and the metal layer.

28. The semiconductor device of claim 16 wherein the device is one of a non-volatile memory device, a volatile memory device, a DRAM volatile memory device, an SRAM volatile memory device, a NAND-type non-volatile memory device, a NOR-type non-volatile memory device, and a PRAM memory device.
